(19) United States
(12) Patent Application Publication
(10) Pub. No.: US 2008/0230108 A1
(43) Pub. Date: Sep. 25, 2008

(54) SOLAR PANEL APPARATUS AND METHOD UTILIZING POUNDED VERTICAL SUPPORTS

(76) Inventors: Marvin S. Keshner, Sonora, CA (US); Erik Vaaler, Redwood City, CA (US)

Correspondence Address: WEISS & MOY PC, 4204 NORTH BROWN AVENUE, SCOTTSDALE, AZ, 85251, US

(21) Appl. No.: 11/689,952

(22) Filed: Mar. 22, 2007

(51) Int. Cl. H01L 31/048

(52) U.S. Cl. 136/244

(57) ABSTRACT

A solar panel array that comprises at least two vertical supports, a horizontal support, and at least one solar panel positioned thereon. The vertical supports are provided with a gradual twist, preferably following an extrusion process, so as to permit the supports to rotate as they are pounded into the ground.

### FIELD OF THE INVENTION

The present invention relates generally to solar panel arrays and, more particularly, to a solar panel array apparatus and method utilizing vertical supports that may be installed through a pounding action, and that are adapted to rotate during the pounding process to permit a more secure ground installation.

### BACKGROUND OF INVENTION

Prior art installation designs and processes for mounting photovoltaic or other types of solar panels to the ground (as opposed to, for example, the roof of a building) are intended to hold the solar panels against wind, hail, rain and snow. In one type of prior art installation, solar panels are mounted at a fixed angle relative to a horizontal support(s), with the horizontal support(s) in turn being secured to two or more vertical supports. In another variation, solar panels are mounted on a platform, which in turn is secured to two or more vertical supports, with the platform being capable of tilting along a single axis to follow the angle of the sun.

In prior art installations, it is often the case that the vertical supports are placed into large holes dug into the ground, which are then filled with reinforced concrete to securely hold the vertical supports in place. Occasionally, reinforced concrete foundations are created and the vertical supports are bolted to the concrete.

Recently, several companies have offered vertical supports that have screw threads, such as those manufactured by American Earth Anchors®. These have a thread much like a wood screw and are often cast or machined to create the thread. As a result, they are relatively expensive to manufacture. Prior art screw-in supports must be rotated as they enter the earth. Machines have been developed that apply a large and steady downward force, and, at the same time, a rotation to “screw” the support into the ground. The rotation enables the support to be screwed into the ground and the steady downward force enables the support to penetrate into dense soils. However, these machines are expensive and the process of screwing in a support is slow. As a consequence, the total cost of installation per support is relatively high.

Prior art designs, as herein described by way of example, are relatively expensive and significantly increase the total cost of a system that uses solar panels to capture energy from the sun, making it more expensive to utilize solar technology. A need exists for apparatuses and methods for more economically installing solar panel arrays in the ground. In particular, a need exists for vertical support components of a solar panel array that are relatively inexpensive to fabricate and that may be installed without the need for a concrete foundation or the use of relatively expensive equipment for screwing supports into the ground. The present invention satisfies this need, and provides other related advantages.

### SUMMARY OF THE INVENTION

In accordance with an embodiment of the present invention, a solar panel apparatus is disclosed. The apparatus comprises, in combination: first and second vertical supports; wherein the first and second vertical supports are comprised of extruded metal having a twist of sufficient length to permit ground installation utilizing a post pounding device in a manner that permits the first and second vertical supports to rotate during pounding; a horizontal support positioned on the first and second vertical supports; at least one solar panel positioned on the horizontal support.

In accordance with another embodiment of the present invention, a method for installing a solar panel array is disclosed. The method comprises: providing first and second vertical supports; wherein the first and second vertical supports are comprised of extruded metal having a twist of sufficient length to permit ground installation utilizing a post pounding device in a manner that permits the first and second vertical supports to rotate during pounding; providing first and second caps adapted to be positioned on a top portion of each of the first and second vertical supports; providing at least one horizontal support; providing at least one solar panel; positioning the first cap on the top portion of the first vertical support; positioning the second cap on the top portion of the second vertical support; positioning a post pounding device proximate the first vertical support; utilizing the post pounding device to pound the first cap, causing a bottom portion of the first vertical support to enter the ground and further causing the first vertical support to rotate as it penetrates deeper into the ground; utilizing the post pounding device to pound the second cap, causing a bottom portion of the second vertical support to enter the ground and further causing the second vertical support to rotate as it penetrates deeper into the ground; positioning the horizontal support on the first and second vertical supports; and positioning at least one solar panel on the horizontal support.

In accordance with a further embodiment of the present invention, a method for installing a solar panel array is disclosed. The method comprises: providing first and second vertical supports; wherein the first and second vertical supports are comprised of extruded metal having a twist of approximately one rotation per linear foot; providing first and second caps adapted to be positioned on a top portion of each of the first and second vertical supports; wherein the first and second caps further comprise means for permitting them to rotate relative to the first and second vertical supports during pounding of the first and second caps; providing at least one horizontal support; providing at least one solar panel; positioning the first cap on the top portion of the first vertical support; positioning the second cap on the top portion of the second vertical support; positioning a post pounding device proximate the first vertical support; utilizing the post pounding device to pound the first cap, causing a bottom portion of the first vertical support to enter the ground and further causing the first vertical support to rotate as it penetrates deeper into the ground; utilizing the post pounding device to pound the second cap, causing a bottom portion of the second vertical support to enter the ground and further causing the second vertical support to rotate as it penetrates deeper into the ground; positioning the horizontal support on the first and second vertical supports; and positioning at least one solar panel on the horizontal support.

### BRIEF DESCRIPTION OF THE DRAWINGS

FIG. 1 is a perspective view of a prior art, stationary solar panel array.

FIG. 2 is a perspective view of a prior art, single-axis tracking, solar panel array.

FIG. 3 is a top, cross sectional view of a vertical support component of a solar panel apparatus consistent with an embodiment of the present invention.

FIG. 4 is a top, cross sectional view of a vertical support component of a solar panel apparatus consistent with another embodiment of the present invention.

FIG. 5 is a side view of a vertical support component of a solar panel apparatus consistent with an embodiment of the present invention.

FIG. 6 is a side view of a vertical support component of a solar panel apparatus, with a cap thereon, consistent with an embodiment of the present invention.

FIG. 7 is a side view of the vertical support component of FIG. 6, illustrating rotation of the vertical support during installation utilizing a pounding process.

FIG. 8 is a perspective view of a solar panel array consistent with an embodiment of the present invention.

### DETAILED DESCRIPTION OF THE PREFERRED EMBODIMENTS

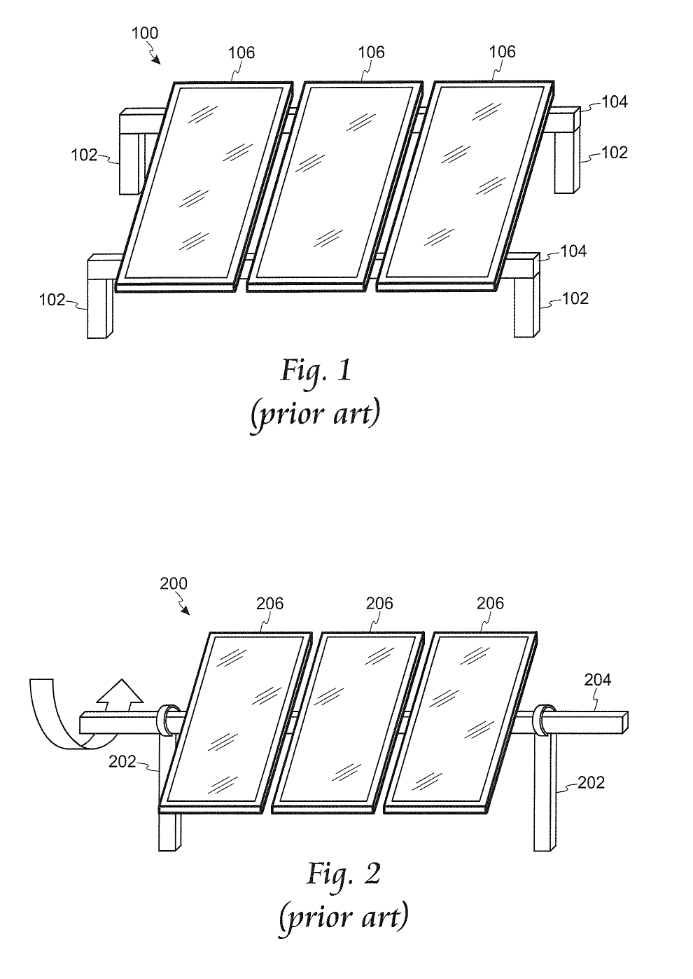

Referring first to FIG. 1, a prior art solar panel array 100 (“array 100”) is shown, illustrating basic components of a ground-installed solar panel array. The main components of an array 100 consist of vertical supports 102, horizontal supports 104 coupled to top portions of the vertical supports 102 in a fixed relationship, and a plurality of solar panels 106 positioned on the horizontal supports 104. As noted above, with prior art arrays like the array 100, the vertical supports are typically installed in concrete or in a reinforced concrete foundation, or may be screwed into the ground utilizing a specialized device for this purpose that rotates the vertical supports while simultaneously maintaining downward pressure.

FIG. 2 illustrates another type of prior art solar panel array—a single-axis solar panel array 200 (“200”). The array 200 utilizes vertical supports 202, which may be installed as described above with respect to the array 100, a horizontal support 204, and a plurality of solar panels 206 positioned on the horizontal support 204. In the array 200, the horizontal support 204 is permitted to rotate or tilt relative to the vertical supports 202 along a single axis, permitting the solar panels 206 to follow the path of the sun.

Referring now to FIG. 8, a solar panel array 10 (“array 10”) consistent with an embodiment of the present invention is disclosed. The array 10 comprises vertical supports 12, a horizontal support 16, and a plurality of solar panels 18.

Referring now to FIGS. 5-8, an embodiment of the vertical supports 12 is described in greater detail. In this embodiment, it can be seen that the vertical supports 12 include a twist 14. The vertical supports 102 are preferably fabricated from metal utilizing an extrusion process. The twist 14 may be imparted by grasping ends of the vertical support 102, after it has been extruded and while it is still hot, and twisting. The amount of twist 14 imparted is significant. A support with too much twist, like that present in a prior art screw-in support, cannot be properly installed utilizing a pounding apparatus as described below. If an attempt was made to pound into the ground a prior art screw-in support, the support would not rotate as pounded, a hole larger than the screw threads would be created, and there would not be compacted soil surrounding the screw threads to enable them to resist upwards forces.

In one embodiment, a twist 14 of approximately one rotation per linear foot may be provided for the vertical support 12, but some deviation from this length would be permitted without departing from the spirit or scope of the present invention. In determining an appropriate length for the twist 14, the motivation is to provide sufficient twist so as to cause the vertical support 12 to rotate as it is pounded into the ground, as opposed to the twist 14 simply causing the displacement of soil during such an installation. Once the vertical support 12 is in the ground, the twist 14 presents a surface with a horizontal component that resists upward forces which would otherwise pull the vertical support 12 out of the ground. This gives the vertical support 12 the ability to resist the upward forces that can result from high winds hitting the flat surfaces of solar panels.

To emphasize, in contrast to the screw thread of a “screw-in” support, the twist 14 as herein described is mostly vertical, so as to appropriately respond to the entirely vertical force applied by the pounding device. The twist 14 only has a relatively small horizontal component, and only creates a relatively small and slow rotation of the vertical support 12 as it is being pounded into the ground. The guides that are formed in the earth have sufficient strength to convert a small fraction of the applied vertical force into a small horizontal force that rotates the vertical supports 12 as they are pounded. (In comparison, for a screw-in post, the screw threads are mostly horizontal and only have a very small vertical component. They would have to convert most of the vertical force into rotational motion, but the earth is insufficiently rigid and strong to accomplish this conversion.)

In one embodiment of this invention, the vertical support 12 is pounded with a conventional post-pounder of the type that may be used to pound ordinary fence posts, such as the Kinghitter III®. Unlike the machines that rotate screw-in supports into the ground and apply large, steady downward pressure at the same time, post-pounders drop a weight from a large height and ram the post into the ground. These post-pounders are simple, reliable, inexpensive and operate quickly.

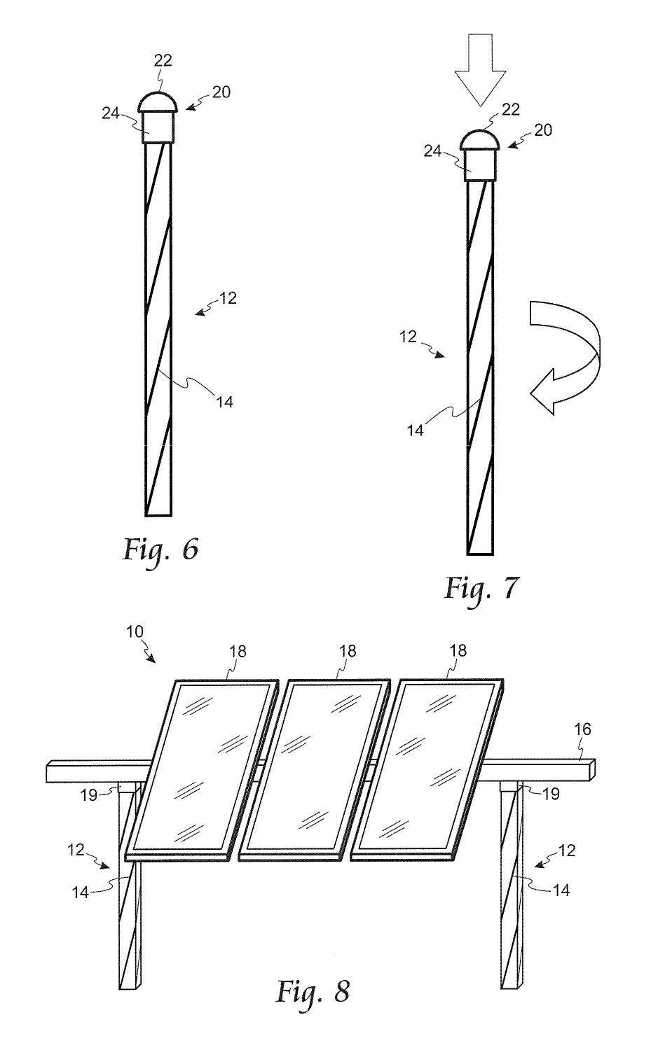

Referring now to FIGS. 6-7, in one embodiment, during the pounding process, the vertical supports 12 may be capped with a cap 20 that is configured to permit the vertical support 12 to rotate relative thereto when an upper portion 22 of the cap 20 is pounded. In one embodiment, the cap 20 has a hemispherical upper portion 22 and a four-sided lower portion 24 that follows the contour of the vertical support 12, so as to permit the upper portion 22 to rotate while it is being hit by the moving weight of the post-pounder machine. In order to further facilitate such rotational movement, it may be desired to interpose bearings or other rotational means between the upper portion 22 and the lower portion 24, so that they may rotate relative to each other.

Referring now to FIG. 8, in one embodiment, once the vertical supports 12 are pounded into the ground to the desired height, the caps 20 are removed and each vertical support 12 is capped with a square cap 19. The square cap 19 may be configured to fit snugly onto a top portion of the vertical support 12. The horizontal support 16 may then be bolted or otherwise coupled to the square cap 19. The combination of the square caps 19 and horizontal support 16 prevent the vertical supports 12 from turning. As a consequence, even with the application of an upward force—for example from wind acting on the panels 18, the vertical supports 12 will not be able to turn, providing the necessary stability for the array 10.

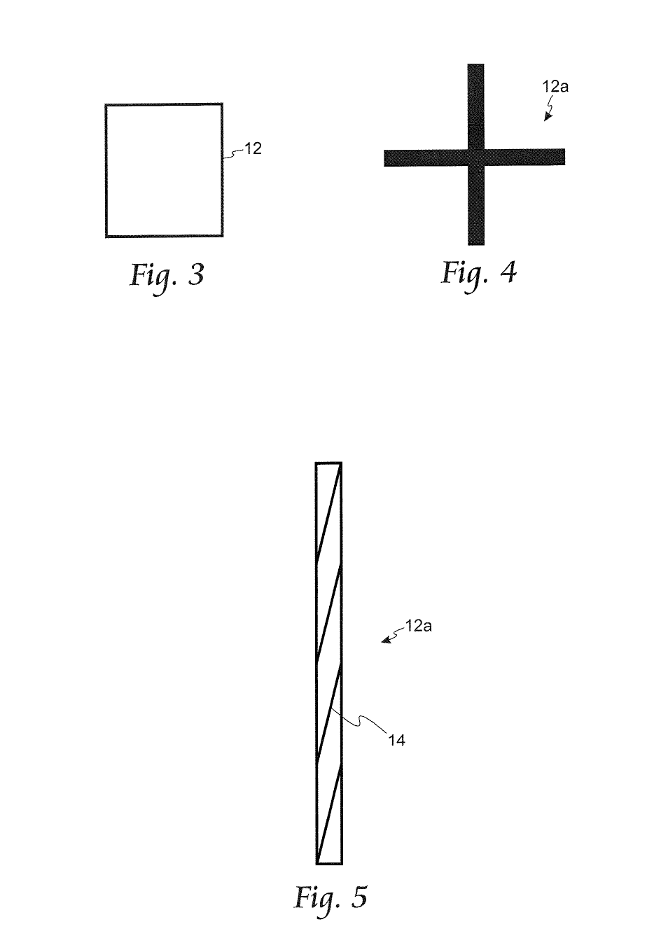

Referring now to FIG. 3, in one embodiment, the vertical support 12 has a four-sided configuration. As shown in FIG. 4, in another embodiment, a vertical support 12a is shown having an X-shaped configuration.

Although particular embodiments of the invention have been described in detail for purposes of illustration, various modifications may be made without departing from the spirit and scope of the invention. Accordingly, the invention is not to be limited, except as by the appended claims.

We claim:

1. A solar panel apparatus comprising, in combination:
first and second vertical supports;
wherein the first and second vertical supports are comprised of metal having a twist of sufficient length to permit ground installation utilizing a post pounding device in a manner that permits the first and second vertical supports to rotate during pounding;
a horizontal support positioned on the first and second vertical supports;
at least one solar panel positioned on the horizontal support.

2. The apparatus of claim 1 wherein the first and second vertical supports have a twist of approximately one rotation per linear foot.

3. The apparatus of claim 1 wherein the first and second vertical supports have a square cross-section prior to twisting.

4. The apparatus of claim 1 wherein the first and second vertical supports have an X-shaped cross-section prior to twisting.

5. The apparatus of claim 1 wherein the first and second vertical supports are comprised of an extruded metal.

6. The apparatus of claim 1 further comprising first and second caps each adapted to be positioned on a top portion of each of the first and second vertical supports during ground installation.

7. The apparatus of claim 6 wherein the first and second caps each comprise an upper portion and a lower portion, and wherein the lower portion is adapted to be coupled to the top portion of the corresponding first and second vertical supports.

8. The apparatus of claim 7 wherein the first and second caps have a lower portion that follows the contour of the vertical support and an upper portion that is hemispherical so as to permit the upper portion to rotate while it is being hit by a moving weight of a post-pounder apparatus.

9. The apparatus in claim 8 further comprising rotational means interposed between the upper and lower portions of the first and second caps.

10. The apparatus of claim 6 wherein the first and second caps are removable.

11. The apparatus of claim 6 further comprising first and second square caps adapted to be positioned on the top portion of each of the first and second vertical supports following removal of the first and second caps.

12. The apparatus of claim 11 wherein the first and second square caps are coupled to the horizontal support so as to prevent the first and second vertical supports from rotating relative thereto.

13. A method for installing a solar panel array, comprising:
providing first and second vertical supports;
wherein the first and second vertical supports are comprised of metal having a twist of sufficient length to permit ground installation utilizing a post pounding device in a manner that permits the first and second vertical supports to rotate during pounding;
providing at least one horizontal support;
providing at least one solar panel;
positioning a post pounding device proximate the first vertical support;
utilizing the post pounding device to pound the first vertical support, causing a bottom portion of the first vertical support to enter the ground and further causing the first vertical support to rotate as it penetrates deeper into the ground;
utilizing the post pounding device to pound the second vertical support, causing a bottom portion of the second vertical support to enter the ground and further causing the second vertical support to rotate as it penetrates deeper into the ground;
positioning the horizontal support on the first and second vertical supports; and
positioning at least one solar panel on the horizontal support.

14. The method of claim 13 wherein the first and second vertical supports have a twist of approximately one rotation per linear foot.

15. The method of claim 13 wherein the first and second vertical supports have a square cross-section prior to twisting.

16. The method of claim 13 wherein the first and second vertical supports have an X-shaped cross-section prior to twisting.

17. The method of claim 13 further comprising extruding the first and second vertical supports and twisting them while still hot.

18. The method of claim 13 further comprising:
providing first and second caps adapted to be positioned on a top portion of each of the first and second vertical supports;
positioning the first cap on the top portion of the first vertical support prior to utilizing the post pounding device to pound the first vertical support; and
positioning the second cap on the top portion of the second vertical support prior to utilizing the post pounding device to pound the second vertical support;
wherein the first and second caps have a lower portion that follows the contour of the vertical support and an upper portion that is hemispherical so as to permit the upper portion to rotate while it is being hit by a moving weight of a post-pounder apparatus.

19. The method of claim 18 further comprising rotational means interposed between the upper and lower portions of the first and second caps.

20. The method of claim 18 further comprising:
removing the first and second caps after the pounding of the first and second vertical supports; and
replacing the first and second caps with square caps prior to positioning the horizontal support on the first and second vertical supports.

21. The method of claim 20 further comprising coupling the first and second square caps to the horizontal support so as to prevent the first and second vertical supports from rotating relative thereto.

22. A method for installing a solar panel array, comprising:
providing first and second vertical supports;
wherein the first and second vertical supports are comprised of metal having a twist of approximately one rotation per linear foot;
providing first and second caps adapted to be positioned on a top portion of each of the first and second vertical supports;
wherein the first and second caps further comprise means for permitting them to rotate relative to the first and second vertical supports during pounding of the first and second caps;
providing at least one horizontal support;
providing at least one solar panel;
positioning the first cap on the top portion of the first vertical support;
positioning the second cap on the top portion of the second vertical support;
positioning a post pounding device proximate the first vertical support;
utilizing the post pounding device to pound the first cap, causing a bottom portion of the first vertical support to enter the ground and further causing the first vertical support to rotate as it penetrates deeper into the ground;
utilizing the post pounding device to pound the second cap, causing a bottom portion of the second vertical support to enter the ground and further causing the second vertical support to rotate as it penetrates deeper into the ground;
positioning the horizontal support on the first and second vertical supports; and
positioning at least one solar panel on the horizontal support.

23. The method of claim 22 wherein the first and second vertical supports have a square cross-section prior to twisting.

24. The method of claim 22 wherein the first and second vertical supports have an X-shaped cross-section prior to twisting.

25. The method of claim 22 further comprising extruding the first and second vertical supports and twisting them while still hot.

26. The method of claim 22 wherein the first and second caps have a lower portion that follows the contour of the vertical support and an upper portion that is hemispherical so as to permit the upper portion to rotate while it is being hit by a moving weight of a post-pounder apparatus and further wherein the rotating means comprises rotating bearings located on an underside of each of the first and second caps.

27. The method of claim 22 further comprising:
removing the first and second caps after the pounding of the first and second vertical supports; and
replacing the first and second caps with square caps prior to positioning the horizontal support on the first and second vertical supports.

28. The method of claim 22 further comprising coupling the first and second square caps to the horizontal support so as to prevent the first and second vertical supports from rotating relative thereto.
